(19) United States
(12) Patent Application Publication
(10) Pub. No.: US 2025/0105595 A1
(43) Pub. Date: Mar. 27, 2025

(54) METHOD OF MANUFACTURING PHOTONIC INTEGRATED DEVICE BASED ON SINGLE-STEP ACTIVE LAYER EPITAXIAL GROWTH

(71) Applicant: ELECTRONICS AND TELECOMMUNICATIONS RESEARCH INSTITUTE, Daejeon (KR)

(72) Inventors: O Kyun KWON, Daejeon (KR); Nam Je KIM, Daejeon (KR); Ho Sung KIM, Daejeon (KR); Mi Ran PARK, Daejeon (KR); Seung Chul LEE, Daejeon (KR); Won Seok HAN, Daejeon (KR)

(21) Appl. No.: 18/895,048

(22) Filed: Sep. 24, 2024

(30) Foreign Application Priority Data
Sep. 25, 2023 (KR) 10-2023-0128454

(51) Int. Cl. H01S 5/20; H01S 5/026; H01S 5/11

(52) U.S. Cl. CPC H01S 5/2077; H01S 5/0261; H01S 5/11

(57) ABSTRACT

The present invention relates to a method of manufacturing a photonic integrated device based on single-step active layer epitaxial growth, and the method includes forming, on a substrate, a reference region having a first bandgap and a region having a bandgap, which is red-shifted relative to the first bandgap, through active layer epitaxial growth, and applying a blue-shift to the substrate to form a region having a second bandgap that is blue-shifted relative to the first bandgap.

### CROSS-REFERENCE TO RELATED APPLICATION

The present application claims priority to and the benefit of Korean Patent Application No. 10-2023-0128454, filed on Sep. 25, 2023, in the Korean Intellectual Property Office, the entire disclosure of which is incorporated herein by reference.

### BACKGROUND

### 1. Field of the Invention

The present invention relates to a method of manufacturing a photonic integrated device based on single-step active layer epitaxial growth, and more particularly, to a method of manufacturing a photonic integrated device by a bandgap steering method.

### 2. Discussion of Related Art

With the expansion of mobile communication services, high-capacity and high-efficiency communication infrastructure is required, and thus, various communication network and mobile component technologies are being utilized. In particular, optical network technology based on optical technology is being used as a key element in configuring mobile communication services and ultra-high-speed internet networks.

Technologies for photonic device components, which are the core of optical networks to support such mobile communication services, must meet the requirements of high speed, high power, long-distance transmission characteristics, and energy reduction to provide ultra-high speed, ultra-connected, and ultra-low-latency services. In particular, operational performance characteristics at high temperatures are important for photonic device components used in outdoor mobile communications. In addition, for long-distance transmission of optical signals, the photonic device components must have high optical output and low power consumption. To this end, there has been a growing interest in recent years in devices based on InAlGaAs materials, as opposed to devices based on conventional InGaAsP materials.

As optical signals become faster, the quality of transmitted optical signals is degraded due to the chirp characteristics of optical signals and the chromatic dispersion characteristics of optical fibers, and photonic device technology employing an external modulation method rather than a direct modulation method is preferred. In the case of photonic devices using such an external modulation method, a laser unit that serves as a light source and a modulator unit that modulates an optical signal must be integrated into a single device chip, and the method generally used is to integrate the laser and modulator units by butt-joint regrowth technology, with a light source and an optical modulator optimized separately.

However, a method of manufacturing photonic device chips by regrowth affects chip yield and increases costs due to manufacturing processes, and may cause problems such as chip reliability due to a regrowth process.

In the case of electro-absorption modulated lasers (EMLs), which are an example of external modulation devices, after establishing respective epitaxial optimization conditions for a light source device and an optical modulator device, the first device is epitaxially grown using a butt-joint method, a portion thereof is then etched away, and then the second device is epitaxially grown and integrated with the first device. In this case, a disadvantage of low yield occurs due to the complexity and reliability issues of process control caused by process defects in the etching process and the introduction of defects during regrowth.

### SUMMARY OF THE INVENTION

The present invention is directed to providing a method of manufacturing a photonic integrated device based on single-step active layer epitaxial growth, which enables regions (functional units) with various semiconductor bandgap ranges within the same device to be integrated into a single chip by a semiconductor bandgap steering method, thereby achieving a wide bandgap range with just single-step active layer epitaxial growth.

According to an aspect of the present invention, there is provided a method of manufacturing a photonic integrated device based on single-step active layer epitaxial growth, the method including forming, on a substrate, a reference region having a first bandgap and a region having a bandgap, which is red-shifted relative to the first bandgap, through active layer epitaxial growth, and applying a blue-shift to the substrate to form a region having a second bandgap that is blue-shifted relative to the first bandgap.

In the present invention, the applying of the blue-shift to the substrate may include forming a region having a third bandgap on the substrate, wherein the third bandgap may be formed by overlapping the red-shift and the blue-shift.

In the present invention, the red-shift may be configured such that red-shifts of two or more different wavelengths are applied.

In the present invention, the red-shift may be performed by a selective region growth (SAG) method.

In the present invention, by adjusting an aperture width of a pattern formed for SAG, red-shifts of two or more different wavelengths may be applied.

In the present invention, the blue-shift may be configured such that blue-shifts of two or more different wavelengths are applied.

In the present invention, the blue-shift may be performed by a quantum-well intermixing (QWI) method.

In the present invention, by adjusting a thickness of a pattern formed for QWI, blue-shifts of two or more different wavelengths may be applied.

In the present invention, the photonic integrated device may include a light source unit, an optical modulation unit, an optical amplification unit, and an optical waveguide, and the light source unit, the optical modulation unit, the optical amplification unit, and the optical waveguide may have different bandgaps.

The method may further include forming an electrode on the substrate.

According to another aspect of the present invention, there is provided a method of manufacturing a photonic integrated device based on single-step active layer epitaxial growth, the method including forming a reference region having a first bandgap on a substrate through active layer epitaxial growth, and applying a red-shift and a blue-shift to the substrate to form a region having a bandgap that is red-shifted relative to the first bandgap and a region having a second bandgap that is blue-shifted relative to the first bandgap.

In the present invention, in the applying of the red-shift and the blue-shift to the substrate, the red-shift may be applied and then the blue-shift may be applied, or the blue-shift may be applied and then the red-shift may be applied.

In the present invention, the applying of the red-shift and the blue-shift to the substrate may include forming a region having a third bandgap on the substrate, wherein the third bandgap may be formed by overlapping the red-shift and the blue-shift.

In the present invention, the red-shift may be configured such that red-shifts of two or more different wavelengths are applied.

In the present invention, the blue-shift may be configured such that blue-shifts of two or more different wavelengths are applied.

According to still another aspect of the present invention, there is provided a method of manufacturing a photonic integrated device, the method including applying a red-shift and a blue-shift to a substrate, on which an active layer having a reference bandgap is formed, to form a region having a bandgap that is red-shifted relative to the reference bandgap and a region having a bandgap that is blue-shifted relative to the reference bandgap, and forming an electrode on the substrate.

In the present invention, in the applying of the red-shift and the blue-shift to the substrate, the red-shift may be applied and then the blue-shift may be applied, or the blue-shift may be applied and then the red-shift may be applied.

In the present invention, the applying of the red-shift and the blue-shift to the substrate may include forming, on the substrate, a region having a bandgap obtained by overlapping the red-shift and blue-shift.

In the present invention, the red-shift may be configured such that red-shifts of two or more different wavelengths are applied.

In the present invention, the blue-shift may be configured such that blue-shifts of two or more different wavelengths are applied.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is an exemplary diagram illustrating a photonic integrated device manufactured by a method of manufacturing a photonic integrated device based on single-step active layer epitaxial growth according to one embodiment of the present invention;

FIG. 2 is an exemplary diagram for describing a method of forming bandgap regions in the method of manufacturing a photonic integrated device based on single-step active layer epitaxial growth according to one embodiment of the present invention;

FIG. 3 is an exemplary diagram for describing selective area growth (SAG) in the method of manufacturing a photonic integrated device based on single-step active layer epitaxial growth according to one embodiment of the present invention;

FIG. 4 is an exemplary diagram for describing quantum-well intermixing (QWI) in the method of manufacturing a photonic integrated device based on single-step active layer epitaxial growth according to one embodiment of the present invention;

FIG. 5 is an exemplary diagram for describing bandgap steering by combining a red-shift and a blue-shift in the method of manufacturing a photonic integrated device based on single-step active layer epitaxial growth according to one embodiment of the present invention;

FIG. 6 is a flowchart for describing the method of manufacturing a photonic integrated device based on single-step active layer epitaxial growth according to one embodiment of the present invention;

FIG. 7 is an exemplary diagram for describing a SAG pretreatment operation in the method of manufacturing a photonic integrated device based on single-step active layer epitaxial growth according to one embodiment of the present invention;

FIG. 8 is an exemplary diagram for describing a QWI pretreatment operation in the method of manufacturing a photonic integrated device based on single-step active layer epitaxial growth according to one embodiment of the present invention;

FIGS. 9 and 10 are exemplary diagrams for describing a comparison between the method of manufacturing a photonic integrated device based on single-step active layer epitaxial growth according to one embodiment of the present invention and a conventional method;

FIGS. 11, 12, 13 and 14 are exemplary diagrams for describing a bandgap steering method in the method of manufacturing a photonic integrated device based on single-step active layer epitaxial growth according to one embodiment of the present invention; and

FIG. 15 is an exemplary diagram for describing the manufacture of a photonic integrated device through the formation of a plurality of bandgap regions based on the method of manufacturing a photonic integrated device based on single-step active layer epitaxial growth according to one embodiment of the present invention.

### DETAILED DESCRIPTION OF EXEMPLARY EMBODIMENTS

Hereinafter, one embodiment of a method of manufacturing a photonic integrated device based on single-step active layer epitaxial growth according to the present invention will be described with reference to the attached drawings. In this process, the thickness of lines or the size of components illustrated in the drawings may be exaggerated for clarity and convenience of description. In addition, terms described below are defined in consideration of the functions in the present invention, and these terms may be varied according to the intent of a user or an operator or a custom. Accordingly, the definitions of such terms should be given on the basis of the content throughout the specification.

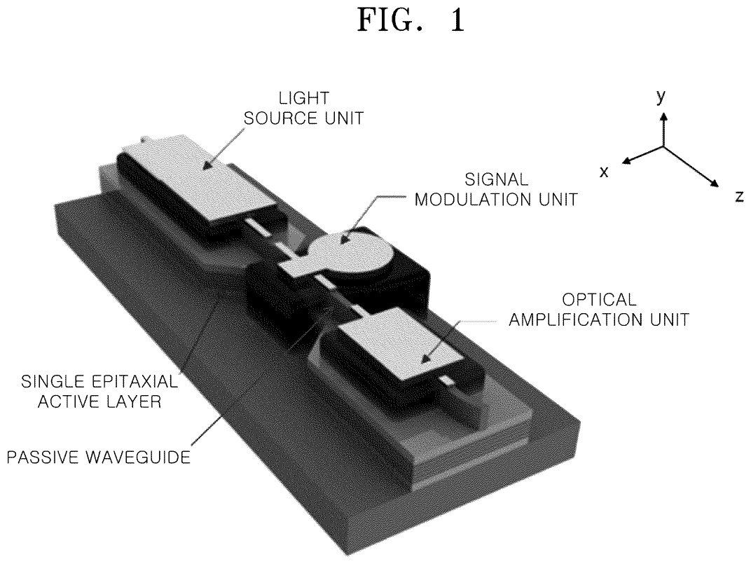

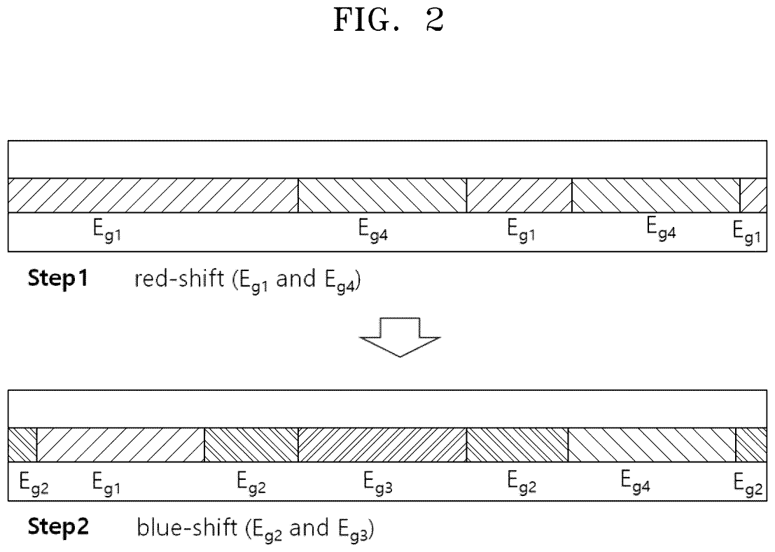

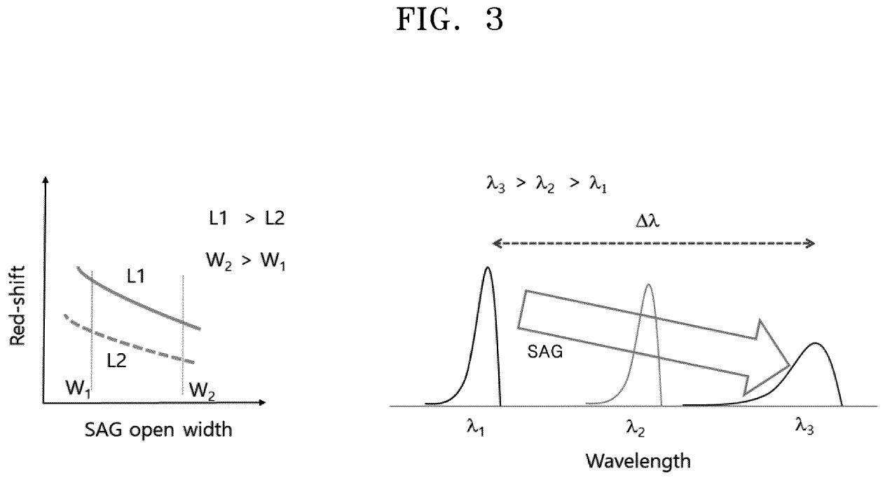

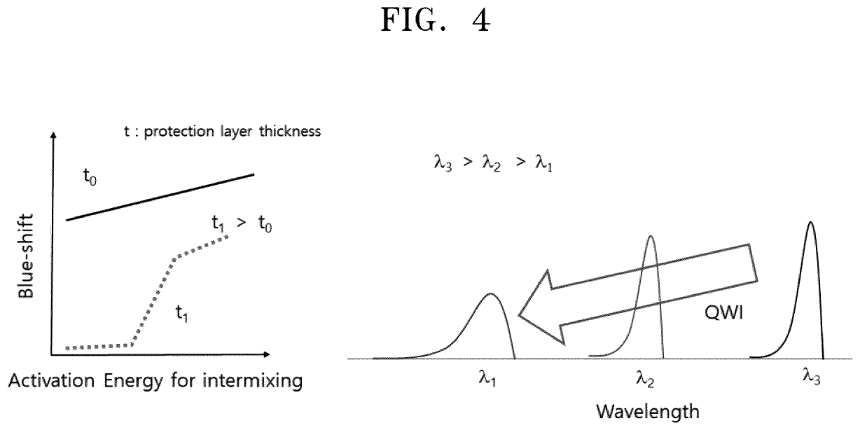

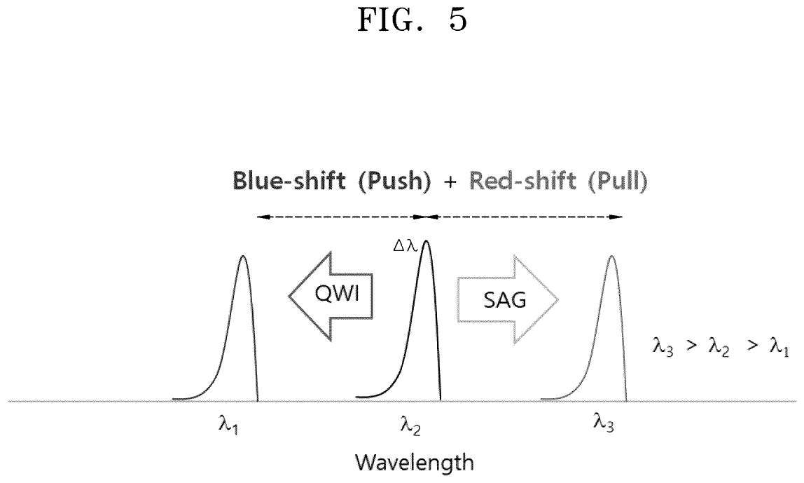

FIG. 1 is an exemplary diagram illustrating a photonic integrated device manufactured by a method of manufacturing a photonic integrated device based on single-step active layer epitaxial growth according to one embodiment of the present invention, FIG. 2 is an exemplary diagram for describing a method of forming bandgap regions in the method of manufacturing a photonic integrated device based on single-step active layer epitaxial growth according to one embodiment of the present invention, FIG. 3 is an exemplary diagram for describing selective area growth (SAG) in the method of manufacturing a photonic integrated device based on single-step active layer epitaxial growth according to one embodiment of the present invention, FIG. 4 is an exemplary diagram for describing quantum-well intermixing (QWI) in the method of manufacturing a photonic integrated device based on single-step active layer epitaxial growth according to one embodiment of the present invention, and FIG. 5 is an exemplary diagram for describing bandgap steering by combining red-shift and blue-shift in the method of manufacturing a photonic integrated device based on single-step active layer epitaxial growth according to one embodiment of the present invention.

As shown in FIG. 1, a photonic integrated device manufactured by the method of manufacturing a photonic integrated device based on single-step active layer epitaxial growth according to one embodiment of the present invention may be an electro-absorption modulated laser (EML) device integrated with a semiconductor optical amplifier (SOA). The EML device may include active components such as a light source unit, a signal modulation unit (optical modulation unit), and an optical amplification unit (signal amplification unit), and passive components such as passive waveguides.

In order to describe the structure of the device according to the present invention, x-y and x-z cross sections are shown in FIG. 1, and a z-axis direction may correspond to a direction of a waveguide of a photonic device.

In order to generate an optical signal from a light source, modulate or amplify the generated optical signal, and effectively transmit the optical signal, an energy bandgap of each component must be independently optimized depending on a function of each component. Bandgaps of the passive waveguides and the passive components must be large to prevent absorption loss of an optical signal, and a bandgap of an optical modulator must have an energy gap appropriately larger than a bandgap of a light source to modulate an optical signal with minimal loss depending on the presence or absence of an electrical signal. In addition, as necessary, the optical amplification unit may need to have a bandgap smaller than the bandgap of the light source.

Thus, when photonic integrated devices are implemented on the same substrate, the integrated devices must be implemented with different bandgaps, and the differences in the required bandgaps for implementation may be significant.

As will be described later, the present invention enables the bandgap of each component to be implemented by applying a red-shift and a blue-shift to the same substrate based on single-step active layer epitaxial growth.

As shown in FIG. 2, first, an active layer with a bandgap energy of E_{g1} is grown on a single crystal substrate. In order to implement photonic integrated devices through bandgap control, one or more different wavelength-shift methods may be applied. As an example, in order to utilize a red-shift, dielectric film deposition and patterning processes for SAG may be performed on a semiconductor substrate, and sequentially, the active layer with the bandgap energy of E_{g1} may be grown. Through this, sections with energy bandgaps of E_{g4} and E_{g1} may be formed in a SAG region and a non-SAG region, respectively.

Afterwards, sequentially, a QWI process may be performed to utilize a blue-shift. Optionally, in order to form QWI regions, dielectric protection film patterning is performed, and then, sequentially, a point defect generation process necessary for QWI is performed across the entire substrate. Subsequently, bandgap steering is performed through an activation process that utilizes the point defects generated within the semiconductor to induce QWI. E_{g2} and E_{g3} regions are regions selected as QWI regions, and the E_{g3} region may be a region in which both the red-shift by SAG and the blue-shift by QWI are applied.

In other words, a quantum well structure of a single active layer grown by the SAG method is used as a reference to perform a process of forming a reference section and a red-shift section. In the next operation, a QWI process is applied to the substrate to which the SAG is applied, and in this case, a portion of the reference quantum well structure and a portion of the red-shift section are protected by the dielectric film, and the exposed surface undergoes a blue-shift through the QWI process. The region protected by the dielectric film maintains the bandgap of the previous process, but the reference region exposed in the second operation during the QWI process experiences an increase in bandgap due to the blue-shift effect, and the QWI-exposed portion of the SAG red-shifted region exhibits a bandgap change equivalent to the difference caused by offsetting effects of the red-shift and the blue-shift.

As described above, by using one or more methods of the red-shift and the blue-shift, it is possible to utilize a wide energy range (wavelength range) while maintaining the quality of quantum wells, so that the performance of the integrated device can be maintained by optimizing the components with different bandgaps.

Bandgap energy magnitudes thus formed may be E_{g2}>E_{g3}>E_{g1}>E_{g4}, which can be assigned to functions of the passive optical waveguide, the signal modulation unit, the light source unit, and the optical amplification unit, respectively, and may be applied and implemented in an EML integrated device, in which the optical amplification unit is integrated, as shown in FIG. 1.

As an example, a blue-shift of 20 nm to 30 nm in magnitude may be preferred for the signal modulation unit, and a red-shift of 10 nm or more, or the same bandgap compared to the reference may be preferred for the optical amplification unit. In addition, the passive waveguide in the photonic integrated device should have no absorption loss of the optical signal, and thus, a blue-shift of 50 nm or more compared to the reference may be preferred for the passive waveguide.

Here, the SAG method is a method that involves forming a patterned dielectric film on a substrate as a mask, and then performing epitaxial growth of compound semiconductors such as InGaAsP and InAlGaAs, and in this case, group III reactive elements deposited on the mask migrate to a growth surface of the substrate and further enter the growth surface exposed by the mask to increase a growth rate, and in this process, the difference in surface migration rates of the group III elements on the growth surface causes a spatial composition change in an epitaxially grown film exposed between the masks. In addition, QWI is a method of adjusting a semiconductor bandgap by utilizing the intermixing of interface compositions of well and barrier layers due to inter-diffusion in a quantum well layer.

In compound semiconductor systems such as InP, InGaAsP, and InAlGaAs, the wavelength-shift method using the SAG method primarily results in an increased growth rate in the SAG region and the effects of compressive stress and red-shift (bandgap reduction) due to the introduction of a relatively excessive amount of In elements. As can be seen in FIG. 3, in the SAG method, bandgap steering is possible only in the direction of a red-shift, in which the bandgap decreases, and it is possible to increase a wavelength shift (Δλ) of a quantum well active layer by increasing a width (L1>L2) of a SAG dielectric mask or decreasing a width (W₁<W₂) of a SAG aperture, but, the quality of the quantum well, which may be evaluated by a photo-luminescence (PL) intensity and full width half maximum (FWHM), may be degraded due to increased compressive stress and increased thickness.

In the case of QWI, inducing inter-diffusion compositional intermixing in a high-quality single-crystal quantum well structure requires high activation energy at high temperatures, but this process must be performed at temperatures that are not desirable considering compound semiconductor processes. In addition, it is not possible to achieve selectivity of regions with different bandgaps through QWI on the same substrate. An alternative method is to artificially inject point defects, such as vacancies or interstitials, into the quantum well to promote inter-diffusion between the quantum well and barrier layers.

In the present invention, as a method for achieving a blue-shift, point defects are injected near the surface of a semiconductor by using physical collision energy of deposited elements generated during physical dielectric thin film deposition. In addition, in order to achieve selective wavelength shifts in different regions, a dielectric protection film is deposited and patterned, and then, a point defect generation process using a physical method is performed across the entire substrate, so that the concentration of point defects generated on the semiconductor surface can be controlled according to the thickness of the protection film. The next operation is to diffuse the injected point defects into the quantum well structure to allow for inter-diffusion of the compositions, this allows bandgap steering in selected regions through wavelength shifts.

FIG. 4 shows the degree of blue-shift according to a thickness (t₁>t₀) of the dielectric protection film and activation energy. In some embodiments, a rapid thermal annealing (RTA) method may be used to provide the activation energy. The dielectric protection film limits the concentration of point defects entering the semiconductor and requires high activation energy to achieve wavelength shift effects through QWI. Thus, an appropriate RTA temperature for activation must be selected in consideration of the overall semiconductor process.

The wavelength shift due to QWI is caused by changes in the bandgap energy of the quantum well, which results from the compositional intermixing between the quantum well and the barrier layers, and thus, as QWI increases, the bandgap shifts in the direction of the blue-shift (short wavelength). However, similar to SAG, the intermixing in the quantum well structure may degrade the quality of the quantum well, which is evaluated by the PL intensity and FWHM.

As such, when using either SAG or QWI individually, a significant increase in bandgap difference may considerably degrade the optical properties of the corresponding functional unit.

On the other hand, the method of the present invention allows for a wide range of bandgap steering (wavelength shift) by using one or more combinations of opposing red-shift and blue-shift methods, while maintaining the quality of the quantum well (PL intensity and PL FWHM).

The method of the present invention does not require etching and regrowth processes for each different bandgap region, resulting in a very simple manufacturing process and high reliability.

As can be seen in FIG. 5, using the optimal structure of a single active layer epitaxy of E_{g1} as the reference (referred to as a reference active layer), regions with smaller bandgaps are formed using the red-shift method and the above-described SAG process, while regions with larger bandgaps are formed using the blue-shift method and multiple applications of the above-described QWI method. In addition, regions with various intermediate bandgaps may be implemented by using a combination of the red-shift and the blue-shift.

The present invention uses methods with opposite wavelength shift tendencies for the reference active layer, thereby minimizing the degradation of optical properties caused by the deformation of the quantum well structure due to wavelength shifts while simultaneously utilizing the blue-shift (push) and the red-shift (pull) to achieve a wide range of wavelength shifts and significant bandgap variations.

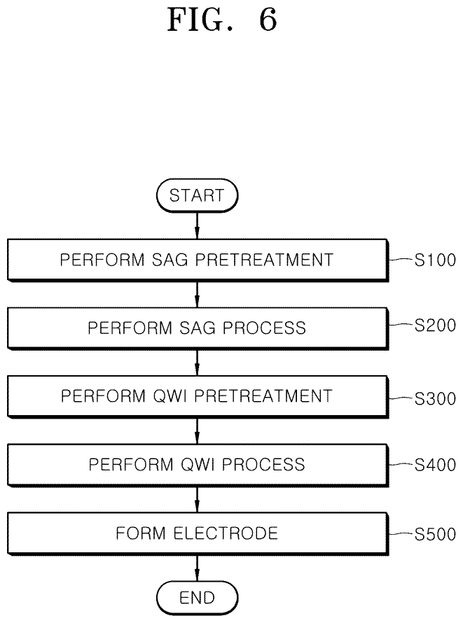

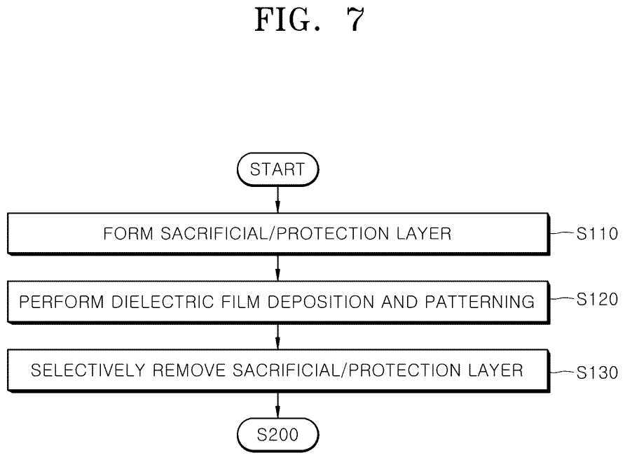

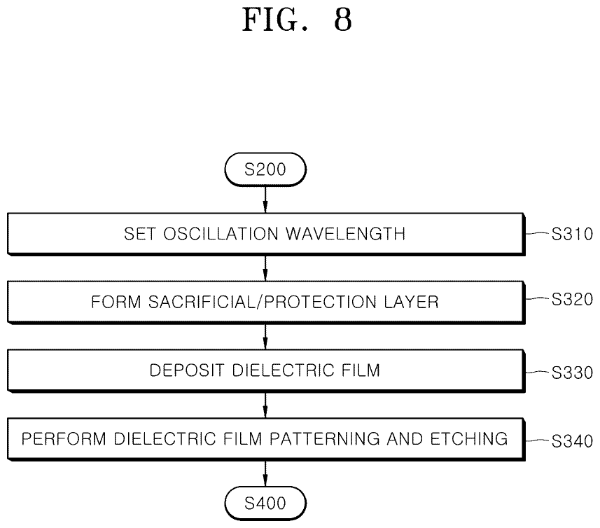

FIG. 6 is a flowchart for describing the method of manufacturing a photonic integrated device based on single-step active layer epitaxial growth according to one embodiment of the present invention, FIG. 7 is an exemplary diagram for describing a SAG pretreatment operation in the method of manufacturing a photonic integrated device based on single-step active layer epitaxial growth according to one embodiment of the present invention, and FIG. 8 is an exemplary diagram for describing a QWI pretreatment operation in the method of manufacturing a photonic integrated device based on single-step active layer epitaxial growth according to one embodiment of the present invention.

As shown in FIG. 7, in the method of manufacturing a photonic integrated device based on single-step active layer epitaxial growth according to one embodiment of the present invention, first, SAG pretreatment operation S100 is performed.

As shown in FIG. 8, the SAG pretreatment operation may include sacrificial/protection layer forming operation S110, dielectric film deposition and patterning operation S120, and sacrificial/protection layer selective removal operation S130.

In consideration of potential damage that may occur during the SAG process, a semiconductor sacrificial layer (or protection layer) may be pre-grown on the single crystal substrate. Sequentially, dielectric film deposition for SAG and dielectric film patterning for bandgap steering through red-shift are performed through SAG, and after the SAG patterning and before growing an active layer of E_{g1}, an exposed semiconductor sacrificial layer may be removed to expose a defect-free semiconductor layer for high-quality active layer growth.

Thereafter, SAG process operation S200 is performed. Through the SAG process operation, the active layer of E_{g1} may be grown through SAG growth, and active layers in the E_{g1} and E_{g4} regions may be formed.

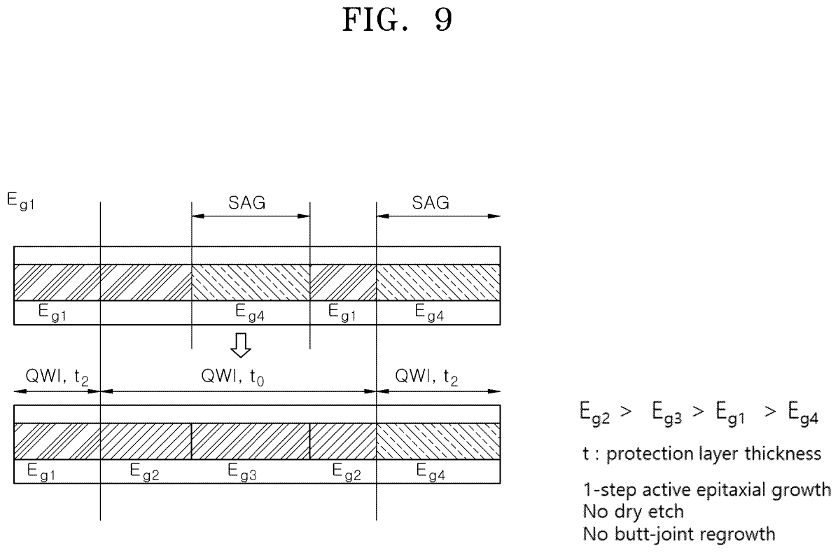

Subsequently, QWI pretreatment operation S300 is performed. As shown in FIG. 9, the QWI pretreatment operation may include oscillation wavelength setting operation S310, sacrificial/protection layer forming operation S320, dielectric film deposition operation S330, and dielectric film patterning and etching operation S340.

After a grating process that determines a laser oscillation wavelength, the semiconductor sacrificial layer (or protection layer) may be pre-grown on the single crystal substrate in consideration of damage that may occur during the QWI process. In order for bandgap steering through a blue-shift, a dielectric film is deposited over the entire surface of an epitaxial substrate, and a thickness of the dielectric film may be varied locally depending on the desired degree of bandgap steering (t₂>t₁> t₀). In a blue-shift process, regions in which bandgap changes are not desired can have a dielectric thickness of t₂, and the thickness can be adjusted to t₁ or to depending on the degree of the QWI effect.

For example, in the case of a passive waveguide, a large blue-shift is desirable, and thus, in order to maximize the QWI effect, the passive waveguide can have the smallest thickness of to on the substrate, or the dielectric film may be completely removed.

Thereafter, QWI process operation S400 is performed. The physical point defect generation process is performed on the patterned substrate of the thickness of the dielectric film for QWI, the concentration of the injected point defects varies depending on the thickness of the dielectric film for QWI in each region, and during the same QWI activation process, differences in the degree of blue-shift may result in the formation of regions with different bandgaps of E_{g2} and E_{g3}.

In addition, electrode formation operation S500 is performed to complete the product.

On the substrate where the QWI process is completed, the sacrificial/protection layer, which was pre-grown to protect the epitaxial surface from the dielectric film deposition and etching processes, may be removed, and sequentially, p-clad and semiconductor electrode layers for forming semiconductor electrodes may be grown. After a single active layer with E_{g1} bandgap energy is grown, regions with E_{g1}, E_{g2}, E_{g3}, and E_{g4} bandgaps are formed through previous processes, the active layer may be embedded by the growth of the semiconductor electrode layer. The epitaxial substrate thus prepared may form the light source unit in the E_{g1} region, the optical modulation unit in the E_{g3} region, the optical amplification unit in the E_{g4} region, and the passive waveguide in the E_{g2} region during a semiconductor photonic device manufacturing process, and which may be fabricated as an EML device in which an integrated optical amplifier is provided on a single chip.

Meanwhile, in some embodiments of the present invention, the electrode formation operation may be performed before the QWI process.

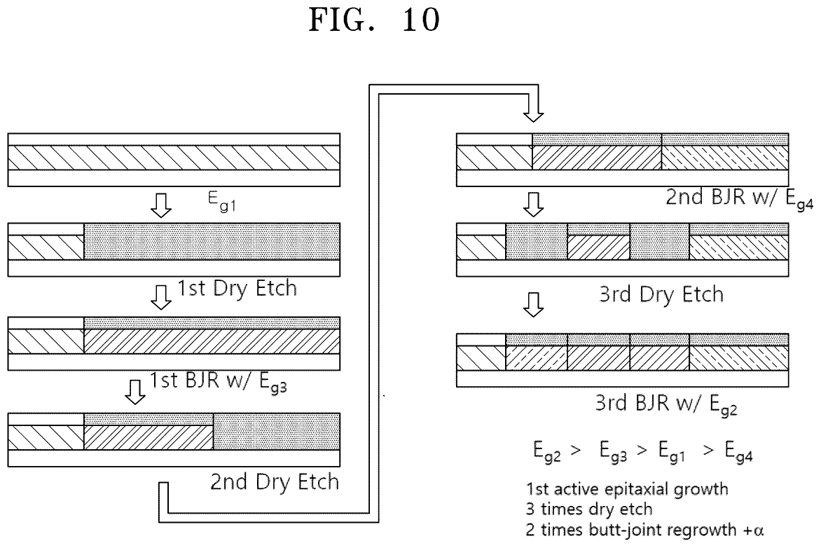

FIGS. 9 and 10 are exemplary diagrams for describing a comparison between the method of manufacturing a photonic integrated device based on single-step active layer epitaxial growth according to one embodiment of the present invention and a conventional method.

Under the condition in which devices with the same structure are manufactured, FIG. 9 illustrates the method presented by the present invention, which uses single active layer growth and a wavelength-shift method, while FIG. 10 illustrates the conventional method.

In order to form the same structure composed of integrated regions with bandgaps of E_{g1}, E_{g2}, E_{g3}, and E_{g4}, the method according to the present invention involves, in the first operation, growing an active layer with the bandgap of E_{g1} and forming a region with the bandgap of E_{g4} by inducing a red-shift through SAG on the single crystal substrate. To this end, as described above, patterning of the dielectric film for SAG and related manufacturing processes are performed on the single crystal substrate to induce a red-shift through SAG. Growth conditions for the active layer are optimized for the bandgap of E_{g1}, and in the SAG section regions, the red-shift may be induced to achieve the target bandgap of E_{g4}.

In the second operation, the QWI process may be applied as a method for a blue-shift. In order to achieve a selective blue-shift through the QWI process, a dielectric protection layer (with a thickness of t₂) is deposited, patterned for each region, and then etched away (the thickness after etching removal may be to). Thereafter, the entire surface of the QWI patterned substrate undergoes a process operation to physically inject point defects into the semiconductor surface, and as the point defects are injected and diffused into the quantum well layer, constituent elements intermix, leading to an increase in the bandgap of the quantum well layer through the blue-shift, thereby forming a new bandgap.

Finally, the regions formed with bandgaps of E_{g1} and E_{g4} are protected by the dielectric protection film (to), so that the bandgaps may remain constant during the QWI process. On the other hand, in regions where the dielectric protection film is completely removed or remains very thin (to), blue-shift characteristics are exhibited due to the QWI process. Some regions with the bandgap of E_{g1}, which were protected during the SAG process, undergo the blue-shift due to the QWI process to be changed to E_{g2}, and some regions that were red-shifted to E_{g4} through the SAG process undergo the blue-shift due to the QWI process, resulting in a bandgap change equal to an offset (Δλ_blue-shift-Δλ_red-shift) between the two processes, so that the bandgap becomes E_{g3}.

FIG. 10 illustrates a conventional manufacturing method required to implement an integrated structure composed of regions respectively having bandgaps of E_{g1}, E_{g2}, E_{g3}, and E_{g4}. First, a quantum well active layer with a bandgap energy of E_{g1} is grown on a substrate. In the next operation, an etching process is performed using a butt-joint method, which is a conventional integration method, and then an active layer with a bandgap energy of E_{g3} is regrown. Sequentially, in order to integrate bandgap regions of E_{g4} and E_{g2}, an etching process and a butt-joint regrowth process are repeatedly performed.

In the exemplified butt-joint integration method, the precision of an etching process thickness and a regrowth thickness is important, and in this case, it is important to control damage to the semiconductor surface caused by etching and defects generated at the interface during regrowth. The process operation becomes complex due to the repetitive etching and regrowth processes, and the process is complicated because precise thickness control is required during etching and regrowth. In addition, damage caused by etching and the control of interfacial defects during regrowth may lead to process difficulties, thereby potentially reducing the reliability of the integrated devices, lowering yield, and increasing device manufacturing costs. In particular, in material systems such as Al-based compounds, in which controlling defects on the exposed epitaxial surface caused by etching is difficult, there may be greater difficulties in managing processes and device reliability.

On the other hand, the technology according to the present invention enables the manufacture of monolithically integrated photonic devices by using only the growth of a single active layer with a bandgap of E_{g1}, without the need for repeated etching and regrowth processes for active layers with different bandgaps, by utilizing the red-shift and blue-shift methods.

Accordingly, problems such as process complexity due to repeated etching and regrowth and device reliability issues due to etching and regrowth interface treatment may be solved, this enables process simplification and enhances the reliability of the photonic integrated device.

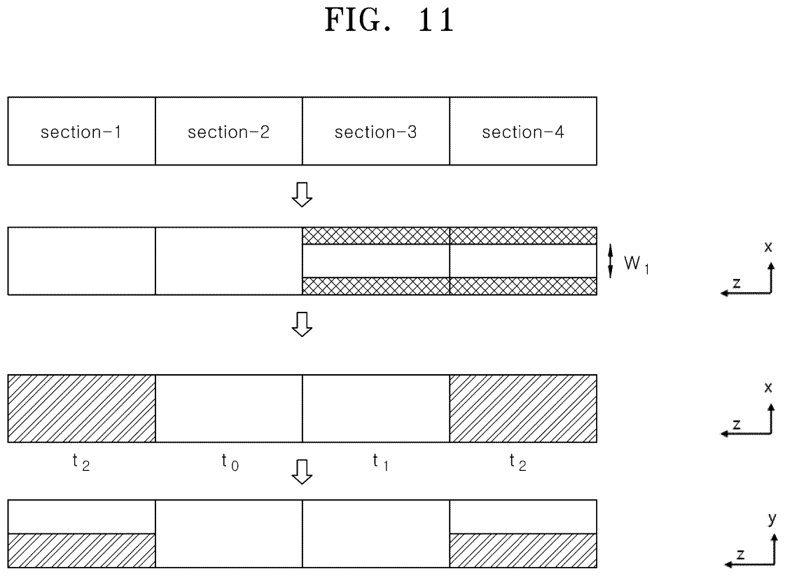

FIGS. 11 to 14 are exemplary diagrams for describing a bandgap steering method in the method of manufacturing a photonic integrated device based on single-step active layer epitaxial growth according to one embodiment of the present invention.

FIG. 11 illustrates the process of manufacturing a photonic integrated structure with four regions having different bandgaps, using single active layer growth and a combination of a plurality of wavelength shift methods presented in the present invention.

In FIG. 11, regions 1, 2, 3, and 4 on an x-z plane of the single crystal substrate are assigned to the light source, the passive waveguide, the optical modulation unit, and the optical amplification unit, respectively, and the light source with E_{g1} is defined as a reference. In a second diagram of FIG. 11, patterning for SAG is performed on the regions 3 and 4 to induce a red-shift. A reference active layer with a bandgap of E_{g1} is grown on the substrate on which the SAG patterning process has been completed. By the above-described SAG method, the bandgaps of the regions 1 and 2 remain unchanged at E_{g1}, but the bandgaps of the regions 3 and 4 change to the red-shifted bandgap E_{g4} due to the intended SAG effect. In a third diagram of FIG. 11, in order to selectively control QWI for a blue-shift, the regions 1 and 4 may be distinguished using a protection layer (t₂) to suppress QWI, while the region 2 and 3 may be distinguished using a layer (t₀) to induce QWI for the blue-shift. A fourth diagram of FIG. 11 illustrates a dielectric thickness in a direction perpendicular to the x-z plane, where t₂ represents an arbitrary thickness of the dielectric film and to represents a case with no dielectric film (t₂>t₀).

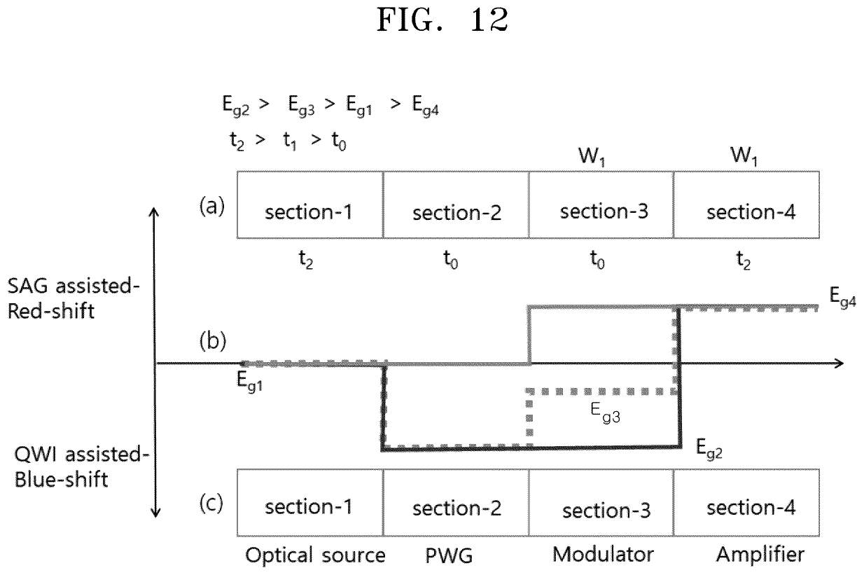

FIG. 12 illustrates bandgap changes according to the method described with reference to FIG. 11. Regions 1 and 4 maintain bandgaps of E_{g1} and E_{g4}, respectively, from the previous process due to the suppression of point defect injection (dose) by the dielectric protection layer, despite subsequent QWI activation processes. On the other hand, regions 2 and 3 undergo a blue-shift due to the QWI effect. In the region 2, a significant blue-shift occurs from E_{g1} to E_{g2}, and in the region 3, the bandgap changes due to an offset between the red-shift from E_{g1} to E_{g4} caused by the previous SAG process and the blue-shift from E_{g1} to E_{g2} caused by the QWI process, this is exemplified by the blue-shift to E_{g3} in the example of the present invention. This allows the implementation of an integrated structure, in which the region 1 serves as the light source unit, the region 2 serves as the passive waveguide, the region 3 serves as the optical modulation unit, and the region 4 serves as the optical amplification unit, through single active layer growth.

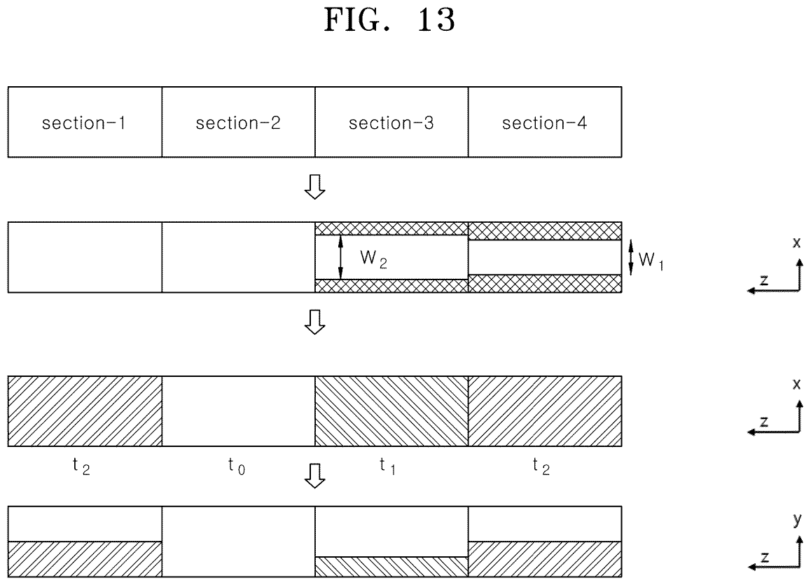

FIG. 13 illustrates the process of manufacturing a photonic integrated structure with four regions, each having different bandgaps, through a combination of single active layer growth and the plurality of wavelength-shift methods for more precise bandgap steering, as presented in the present invention.

In a first diagram of FIG. 13, regions 1, 2, 3, and 4 on an x-z plane of the single crystal substrate are assigned to the light source, the passive waveguide, the optical modulation unit, and the optical amplification unit, respectively, and the light source with E_{g1} is defined as a reference.

According to the above-described FIGS. 11 and 12, wavelength shifts in the regions 2 and 3 are determined by an offset between the red-shift in FIG. 11 (second diagram) and the blue-shift in FIG. 11 (third and fourth diagrams), thereby determining a magnitude of bandgap variation. Since a larger blue-shift compared to the reference may be desirable for the region 3, precise wavelength control and adjustment methods for the regions 3 and 4 will be described through FIG. 13 (second, third and fourth diagrams).

In the operation shown in a second diagram of FIG. 13, the patterning for SAG to induce a red-shift in the regions 3 and 4 may be performed with a plurality of aperture widths W₁ and W₂. The substrate on which the SAG patterning process has been completed using aperture widths W₁ and W₂ is grown into a reference active layer with a bandgap of E_{g1}. By the SAG method, the bandgaps of the regions 1 and 2 remain unchanged at E_{g1}, but the regions 3 and 4 may have a red-shifted bandgap of E_{g4} and a bandgap of E_{g4}, respectively, due to the intended SAG effects of W₁ and W₂ (E_{g4′}>E_{g4}).

In a third and fourth diagrams of FIG. 13, a plurality of thicknesses may be applied to selectively control QWI for a blue-shift. Specifically, the regions 1 and 4 may be distinguished using a protection layer (t₂) to suppress QWI, while the regions 2 and 3 may be distinguished using layers with thicknesses t₀ and t₁, respectively, to induce a blue-shift through QWI. The fourth diagram of FIG. 13 illustrates the dielectric thickness in the direction perpendicular to the x-z plane, and in this example, the thicknesses of the dielectric films have the relationship of t₂>t₁>t₀, where to may also represent a case with no dielectric film.

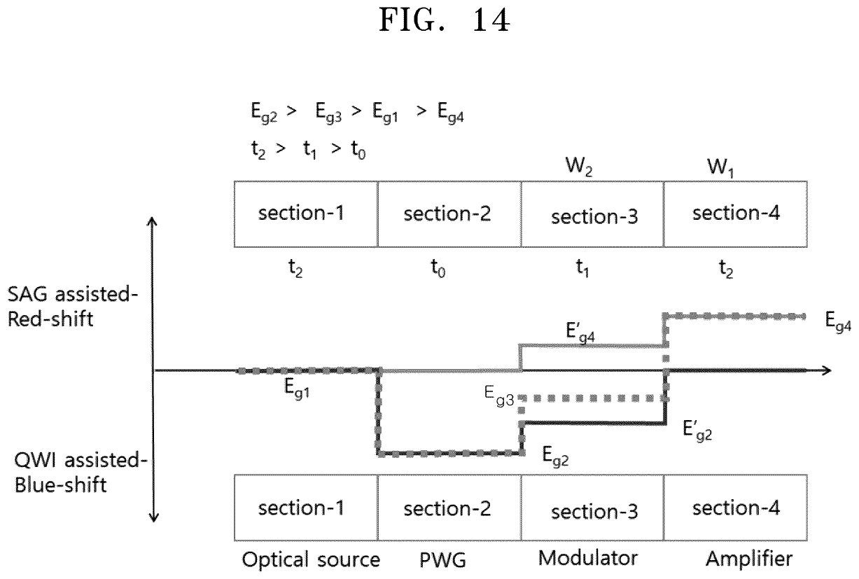

FIG. 14 illustrates bandgap changes according to the method described with reference to FIG. 13. Regions 1 and 4 maintain bandgaps of E_{g1} and E_{g4}, respectively, from the previous process due to the suppression of physical point defect injection by the dielectric protection layer, despite subsequent QWI activation processes. On the other hand, regions 2 and 3 undergo a blue-shift due to the QWI effect. In the region 2, a significant blue-shift occurs from E_{g1} to E_{g2}, but, in the region 3, the thickness of a protection layer for QWI is adjusted to t₁ (where t₂>t₁>t₀) to control the QWI effect to be lower than that of to. Thus, in the region 2, a bandgap change occurs due to an offset between the red-shift from E_{g1} to E_{g4} caused by the previous SAG process and the blue-shift from E_{g1} to E_{g2} caused by the QWI process, and in the region 3, a bandgap change occurs due to an offset between the red-shift from E_{g1} to E_{g4′} and the blue-shift from E_{g1} to E_{g2′} caused by the respective processes. This allows the independent steering of bandgaps in the regions 2 and 3 through wavelength shifts.

By applying this method, it is possible to not only generate regions with four different bandgaps but also to more finely divide the regions and manufacture photonic integrated devices that form desired bandgaps.

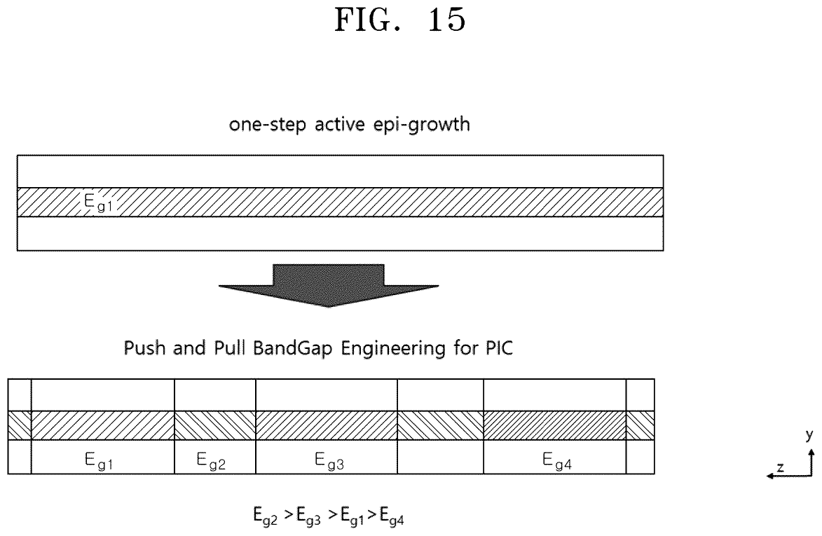

FIG. 15 is an exemplary diagram for describing the manufacture of a photonic integrated device through the formation of a plurality of bandgap regions based on the method of manufacturing a photonic integrated device based on single-step active layer epitaxial growth according to one embodiment of the present invention.

As shown in FIG. 15, in some embodiments of the present invention, after growing a single crystal substrate with a bandgap of E_{g1} through single-step active layer (reference active layer) epitaxial growth, a plurality of regions with different bandgaps can be formed by applying a red-shift and a blue-shift. In other words, when applying the red-shift caused by the above-described SAG, regions with a bandgap of E_{g4} can be grown in addition to the reference region with a bandgap of E_{g1}, but the method is not limited thereto, and various red-shift and blue-shift methods may be applied alternately to the reference region to adjust the bandgap. At this time, a red-shift may be applied first followed by a blue-shift, or the blue-shift may be applied first followed by the red-shift, and the red-shift and the blue-shift may also be performed alternately multiple times.

In addition, in some embodiments of the present invention, a substrate on which a region having a reference bandgap of E_{g1} is already formed (grown) may be prepared in advance, and in such cases, a red-shift and a blue-shift may be applied to the corresponding substrate to manufacture a photonic integrated device according to the present invention.

Meanwhile, process operations for manufacturing a photonic integrated device, which are not described in detail in the present invention, may be performed in the same manner as the conventional method for manufacturing a photonic integrated device. In addition, additional processes (e.g., a washing process, a drying process, and the like) for product production may be added between the above-described processes as needed.

Meanwhile, the present invention may be performed in semiconductor (photonic integrated device) manufacturing equipment configured to perform each process such as SAG, QWI, dielectric film deposition, patterning, etching, or attachment, and a control device of such manufacturing equipment may control operations of each process. Such manufacturing equipment may additionally include a robotic arm, a transfer belt, and the like for transferring products between each process, and various other equipment. In addition, the control device may include a computer-readable storage medium (memory) that stores instructions for controlling the manufacturing equipment to perform each process, and the storage medium is coupled to a processor and configured to cause the processor to perform each operation of the present invention. The configuration of such processing equipment corresponds to the technology widely known in the technical field of the present invention, and thus, a more detailed description will be omitted.

A method of manufacturing a photonic integrated device based on single-step active layer epitaxial growth according to the present invention has an effect of forming regions with different bandgaps by using both a red-shift and a blue-shift together, thereby utilizing a wide energy range (wavelength range) while maintaining the quality of quantum wells.

A method of manufacturing a photonic integrated device based on single-step active layer epitaxial growth according to the present invention has an effect of enabling the manufacture of monolithically integrated photonic devices by utilizing red-transition and blue-transition methods, which eliminate the need for regrowth of active layers with different bandgaps and repetitive etching processes, using only single active layer growth with a reference bandgap.

A method of manufacturing a photonic integrated device based on single-step active layer epitaxial growth according to the present invention has an effect of resolving problems such as process complexity caused by repeated etching and regrowth, and device reliability issues due to etching and regrowth interfacial treatment, and simplifying the manufacturing process of photonic integrated devices and securing reliability.

Although the embodiments of the present invention have been described with reference to the drawings, it would be understood that they are merely examples and various modifications and equivalents thereof may be made by one of ordinary skill in the art. Accordingly, the technical scope of the present invention should be defined in the appended claims.

What is claimed is:

1. A method of manufacturing a photonic integrated device based on single-step active layer epitaxial growth, the method comprising:
forming, on a substrate, a reference region having a first bandgap and a region having a bandgap, which is red-shifted relative to the first bandgap, through active layer epitaxial growth; and
applying a blue-shift to the substrate to form a region having a second bandgap that is blue-shifted relative to the first bandgap.

2. The method of claim 1, wherein the applying of the blue-shift to the substrate includes forming a region having a third bandgap on the substrate,
wherein the third bandgap is formed by overlapping the red-shift and the blue-shift.

3. The method of claim 1, wherein the red-shift is configured such that red-shifts of two or more different wavelengths are applied.

4. The method of claim 1, wherein the red-shift is performed by a selective region growth (SAG) method.

5. The method of claim 4, wherein by adjusting an aperture width of a pattern formed for SAG, red-shifts of two or more different wavelengths are applied.

6. The method of claim 1, wherein the blue-shift is configured such that blue-shifts of two or more different wavelengths are applied.

7. The method of claim 1, wherein the blue-shift is performed by a quantum-well intermixing (QWI) method.

8. The method of claim 7, wherein by adjusting a thickness of a pattern formed for QWI, blue-shifts of two or more different wavelengths are applied.

9. The method of claim 1, wherein the photonic integrated device includes a light source unit, an optical modulation unit, an optical amplification unit, and an optical waveguide, and
the light source unit, the optical modulation unit, the optical amplification unit, and the optical waveguide have different bandgaps.

10. The method of claim 1, further comprising forming an electrode on the substrate.

11. A method of manufacturing a photonic integrated device based on single-step active layer epitaxial growth, the method comprising:
forming a reference region having a first bandgap on a substrate through active layer epitaxial growth; and
applying a red-shift and a blue-shift to the substrate to form a region having a bandgap that is red-shifted relative to the first bandgap and a region having a second bandgap that is blue-shifted relative to the first bandgap.

12. The method of claim 11, wherein in the applying of the red-shift and the blue-shift to the substrate, the red-shift is applied and then the blue-shift is applied, or the blue-shift is applied and then the red-shift is applied.

13. The method of claim 11, wherein the applying of the red-shift and the blue-shift to the substrate includes forming a region having a third bandgap on the substrate,
wherein the third bandgap is formed by overlapping the red-shift and the blue-shift.

14. The method of claim 11, wherein the red-shift is configured such that red-shifts of two or more different wavelengths are applied.

15. The method of claim 11, wherein the blue-shift is configured such that blue-shifts of two or more different wavelengths are applied.

16. A method of manufacturing a photonic integrated device, the method comprising:
applying a red-shift and a blue-shift to a substrate, on which an active layer having a reference bandgap is formed, to form a region having a bandgap that is red-shifted relative to the reference bandgap and a region having a bandgap that is blue-shifted relative to the reference bandgap; and
forming an electrode on the substrate.

17. The method of claim 16, wherein in the applying of the red-shift and the blue-shift to the substrate, the red-shift is applied and then the blue-shift is applied, or the blue-shift is applied and then the red-shift is applied.

18. The method of claim 16, wherein the applying of the red-shift and the blue-shift to the substrate includes forming, on the substrate, a region having a bandgap obtained by overlapping the red-shift and blue-shift.

19. The method of claim 16, wherein the red-shift is configured such that red-shifts of two or more different wavelengths are applied.

20. The method of claim 16, wherein the blue-shift is configured such that blue-shifts of two or more different wavelengths are applied.
